(19) United States
(12) Patent Application Publication
(10) Pub. No.: US 2026/0045768 A1
(43) Pub. Date: Feb. 12, 2026

(54) VERTICAL-CAVITY SURFACE-EMITTING LASER HAVING MULTIPLE REFLECTORS

(71) Applicant: HLJ TECHNOLOGY CO., LTD., Hsinchu County (TW)

(72) Inventors: LI-WEN LAI, Taoyuan City (TW); LI-HUNG LAI, Taoyuan City (TW)

(21) Appl. No.: 18/961,366

(22) Filed: Nov. 26, 2024

(30) Foreign Application Priority Data
Aug. 12, 2024 (TW) 113130082

(51) Int. Cl. H01S 5/183

(52) U.S. Cl. CPC H01S 5/18311

(57) ABSTRACT

A vertical-cavity surface-emitting laser having multiple reflectors is provided. Through implementation of the multiple reflectors, the vertical-cavity surface-emitting laser includes a first optical cavity and a second optical cavity. The second optical cavity is away from a current confinement layer. A beam is mainly emitted after resonating in the second optical cavity. This structure allows the beam not to be scattered by the current confinement layer, such that a light-emitting effect of the vertical-cavity surface-emitting laser is enhanced.

### CROSS-REFERENCE TO RELATED PATENT APPLICATION

This application claims the benefit of priority to Taiwan Patent Application No. 113130082, filed on Aug. 12, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a laser, and more particularly to a vertical-cavity surface-emitting laser.

### BACKGROUND OF THE DISCLOSURE

A conventional vertical-cavity surface-emitting laser includes a current confinement layer. Generally, the current confinement layer is formed by oxides. When resonating in an optical cavity, a beam is often affected by the current confinement layer and is subjected to scattering, thereby negatively affecting a light-emitting effect of a laser.

In the conventional technology, a confinement aperture of the current confinement layer is narrowed to address the above-mentioned problem. However, this action leads to an increase in impedance of the laser, which is unbeneficial for light emission of the laser or prevents light emission unless a greater amount of electricity is used.

Therefore, how to enhance a light-emitting effect of the vertical-cavity surface-emitting laser through improvements in structural design, so as to overcome the above-mentioned deficiencies, has become one of the important issues to be solved in the relevant industry.

### SUMMARY OF THE DISCLOSURE

In response to the above-referenced technical inadequacies, the present disclosure provides a vertical-cavity surface-emitting laser having multiple reflectors. The vertical-cavity surface-emitting laser includes an active layer, a first reflector, a current confinement layer, a second reflector, and a third reflector.

Two opposite sides of the active layer are respectively defined as a first side and a second side. The first reflector is disposed at the first side of the active layer, and has a first reflective surface. The current confinement layer is disposed at the second side of the active layer, and has a confinement aperture. The second reflector is disposed at the second side, and the current confinement layer is disposed between the second reflector and the active layer. Two opposite surfaces of the second reflector are respectively defined as a transmissive surface and a second reflective surface. The transmissive surface faces toward the current confinement layer, the second reflective surface is away from the current confinement layer, and a first optical cavity is formed between the second reflector and the first reflector. The third reflector is disposed at the second side, and the second reflector is disposed between the current confinement layer and the third reflector. The third reflector has a third reflective surface and a light emergent surface that are opposite to each other, the third reflective surface faces toward the second reflector, and a second optical cavity is formed between the second reflector and the third reflector.

A current is injected from the confinement aperture into the active layer, such that a first beam and a second beam are respectively generated at the first side and the second side of the active layer. A first reflected beam is generated after the first beam is reflected by the first reflector. The first reflected beam passes through the active layer, the active layer absorbs a portion of the first reflected beam and excites the first beam and the second beam, and a beam that is part of another portion of the first reflected beam and penetrates the active layer is defined as a first transmitted beam. The second beam and a beam that is part of the first transmitted beam and is reflected by the second reflector are defined as a second reflected beam. The second reflected beam passes through the active layer, and once again excites the active layer to generate the first beam and the second beam. The second beam and a beam that is part of the first transmitted beam and enters the second optical cavity by penetrating the second reflector are defined as a second transmitted beam. The second transmitted beam resonates between the second reflector and the third reflector to generate a laser beam, and the laser beam is emitted from the light emergent surface of the third reflector.

In one of the possible or preferred embodiments, the current confinement layer is an oxide layer.

In one of the possible or preferred embodiments, the first reflector, the second reflector, and the third reflector are each a Bragg reflector.

In one of the possible or preferred embodiments, a reflectance of the first reflector is greater than or equal to 99.9%.

In one of the possible or preferred embodiments, a distance between the second reflector and the third reflector is greater than a distance between the first reflector and the second reflector.

Therefore, in the vertical-cavity surface-emitting laser having the multiple reflectors provided by the present disclosure, by virtue of “each of the first optical cavity and the second optical cavity being formed by the first reflector, the second reflector, and the third reflector,” a beam mainly resonates in the second optical cavity. Since the second optical cavity is away from the current confinement layer, the beam is less likely to be affected by the current confinement layer, and a laser beam is generated and emitted after the beam resonates in the second optical cavity. In this way, a light-emitting effect of the vertical-cavity surface-emitting laser can be enhanced.

Furthermore, through a thickness design of the second reflector, the second transmitted beam in the second optical cavity can be almost 100% reflected when being in contact with the second reflective surface of the second reflector. The second transmitted beam is retained in the second optical cavity for resonance, and the laser beam is eventually emitted from the light emergent surface of the third reflector that has a low reflectance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view showing a use status according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

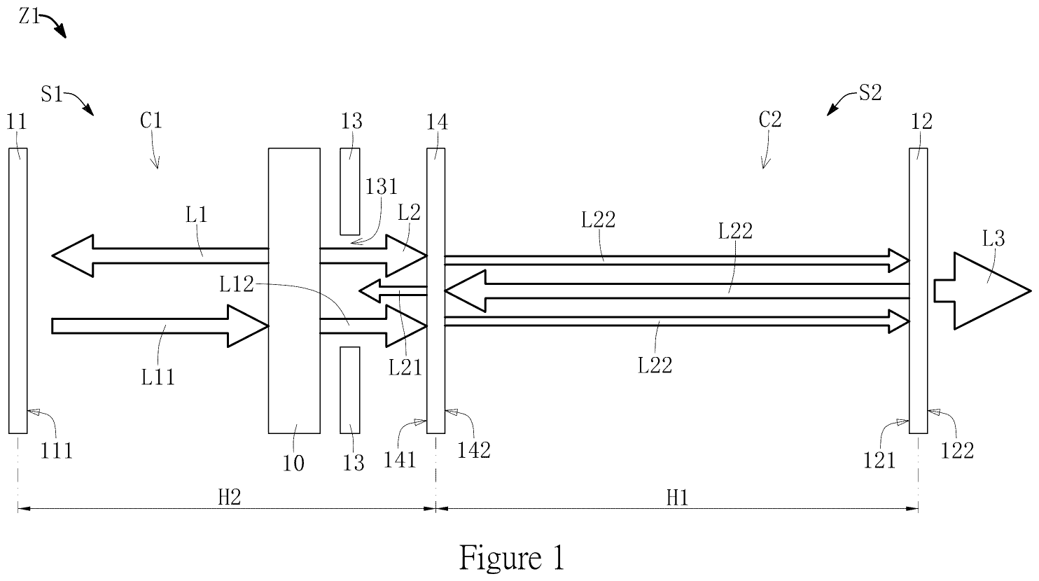

Reference is made to FIG. 1, which is a schematic view showing a use status according to one embodiment of the present disclosure. It should be noted that, in the present embodiment, illustration of a circuit board and a metal electrode is omitted. A vertical-cavity surface-emitting laser Z1 having multiple reflectors includes an active layer 10, a first reflector 11, a current confinement layer 13, a second reflector 14, and a third reflector 12. Two opposite surfaces of the active layer 10 are respectively defined as a first side S1 and a second side S2. The first reflector 11 is disposed at the first side S1 of the active layer 10, and has a first reflective surface 111. The current confinement layer 13 is disposed at the second side S2 of the active layer 10, and has a confinement aperture 131. The second reflector 14 is disposed at the second side S2. The current confinement layer 13 is disposed between the second reflector 14 and the active layer 10. Two opposite surfaces of the second reflector 14 are respectively defined as a transmissive surface 141 and a second reflective surface 142. The transmissive surface 141 faces toward the current confinement layer 13, and the second reflective surface 142 is away from the current confinement layer 13. A first optical cavity C1 is formed between the second reflector 14 and the first reflector 11. The third reflector 12 is disposed at the second side S2, and the second reflector 14 is disposed between the current confinement layer 13 and the third reflector 12. The third reflector 12 has a third reflective surface 121 and a light emergent surface 122 that are opposite to each other, and the third reflective surface 121 faces toward the second reflector 14. A second optical cavity C2 is formed between the second reflector 14 and the third reflector 12.

When a current is injected from the confinement aperture 131 into the active layer 10, a first beam L1 and a second beam L2 are respectively generated at the first side S1 and the second side S2 of the active layer 10. A first reflected beam L11 is generated after the first beam L1 is reflected by the first reflector 11, and passes through the active layer 10. The active layer 10 absorbs a portion of the first reflected beam L11 and excites the first beam L1 and the second beam L2, and a beam that is part of another portion of the first reflected beam L11 and penetrates the active layer 10 is defined as a first transmitted beam L12. The second beam L2 and a beam that is part of the first transmitted beam L12 and is reflected by the second reflector 14 are defined as a second reflected beam L21. The second reflected beam L21 passes through the active layer 10, and once again excites the active layer 10 to generate the first beam L1 and the second beam L2. The second beam L2 and a beam that is part of the first transmitted beam L12 and enters the second optical cavity C2 by penetrating the second reflector 14 are defined as a second transmitted beam L22. The second transmitted beam L22 resonates between the second reflector 14 and the third reflector 12 to generate a laser beam L3, and the laser beam L3 is emitted from the light emergent surface 122 of the third reflector 12.

Specifically, the second reflected beam L21 is formed by a small portion of the second beam L2 and the beam that is part of the first transmitted beam L12 and is reflected by the second reflector 14. The active layer 10 is excited by the second reflected beam L21, and once again generates the first beam L1 and the second beam L2. Accordingly, beams are incessantly generated in the first optical cavity C1.

On the other hand, the second transmitted beam L22 is formed by a large portion of the second beam L2 and the beam that is part of the first transmitted beam L12 and penetrates the second reflector 14. After the second transmitted beam L22 enters the second optical cavity C2 and resonates back and forth, the laser beam L3 is generated and emitted from the light emergence surface 122.

According to certain embodiments, by designing the second reflector 14 to have different thickness, the second transmitted beam L22 in the second optical cavity C2 can be almost 100% reflected after reaching the second reflective surface 142 of the second reflector 14, and the second transmitted beam L22 resonates back and forth in the second optical cavity C2. Eventually, the laser beam L3 is generated.

The active layer 10 includes multiple film layers (e.g., multiple well layers and barrier layers that are alternately stacked and not doped) for formation of a multiple quantum well. Materials of the well layer and the barrier layer are determined according to a wavelength of a beam to be generated. For example, when the beam to be generated is red light, the well layer and the barrier layer can respectively be an InxGa(1-x)P layer and an InAlxGa(1-x)P layer. When the beam to be generated is blue light, the barrier layer and the well layer can respectively be an InxGa(1-x)N layer and an AlxGa(1-x)N layer.

In certain embodiments, the current confinement layer 13 is an oxide layer.

In certain embodiments, the first reflector 11, the second reflector 14, and the third reflector 12 are each a Bragg reflector. In other words, the first reflector 11, the third reflector 12, and the second reflector 14 can each be a distributed Bragg reflector (DBR) that is formed by alter nately stacking two types of thin films (which have different refractive indexes), so as to allow light to be resonantly reflected at a predetermined wavelength. In certain embodiments, a reflectance of the first reflector 11 is greater than or equal to 99.9%.

According to certain embodiments, the second reflector 14 is formed by stacking multiple film layers that are made of materials having different refractive indexes. The quantity and the thickness of the stacked layers can be adjusted in response to requirements of a phase angle and interference, so as to obtain a reflection effect.

In order for the vertical-cavity surface-emitting laser Z1 having the multiple reflectors to output (emit) a pure laser beam (in a normal mode), a distance H1 between the second reflector 14 and the third reflector 12 is greater than a distance H2 between the first reflector 11 and the second reflector 14 in certain embodiments.

It should be noted that, in the first beam L1 and the second beam L2 emitted by the active layer 10 (due to being excited by the current), the second beam L2 is proportionally greater than the first beam L1. In some circumstances, a portion of the second beam L2 that penetrates the second reflector 14 is far greater than a portion of the second beam L2 that is reflected by the second reflector 14.

### Beneficial Effects of the Embodiment

In conclusion, in the vertical-cavity surface-emitting laser having the multiple reflectors provided by the present disclosure, by virtue of “each of the first optical cavity and the second optical cavity being formed by the first reflector, the second reflector, and the third reflector,” a beam mainly resonates in the second optical cavity. Since the second optical cavity is away from the current confinement layer, the beam is less likely to be affected by the current confinement layer, and a laser beam is generated and emitted after the beam resonates in the second optical cavity. In this way, a light-emitting effect of the vertical-cavity surface-emitting laser can be enhanced.

Furthermore, through a thickness design of the second reflector, the second transmitted beam in the second optical cavity can be almost 100% reflected when being in contact with the second reflective surface of the second reflector. The second transmitted beam is retained in the second optical cavity for resonance, and the laser beam is eventually emitted from the light emergent surface of the third reflector that has a low reflectance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A vertical-cavity surface-emitting laser having multiple reflectors, comprising:
an active layer, wherein two opposite sides of the active layer are respectively defined as a first side and a second side;
a first reflector disposed at the first side of the active layer, wherein the first reflector has a first reflective surface;
a current confinement layer disposed at the second side of the active layer, wherein the current confinement layer has a confinement aperture;
a second reflector disposed at the second side, wherein the current confinement layer is disposed between the second reflector and the active layer, two opposite surfaces of the second reflector are respectively defined as a transmissive surface and a second reflective surface, the transmissive surface faces toward the current confinement layer, the second reflective surface is away from the current confinement layer, and a first optical cavity is formed between the second reflector and the first reflector; and
a third reflector disposed at the second side, wherein the second reflector is disposed between the current confinement layer and the third reflector, the third reflector has a third reflective surface and a light emergent surface that are opposite to each other, the third reflective surface faces toward the second reflector, and a second optical cavity is formed between the second reflector and the third reflector;
wherein a current is injected from the confinement aperture into the active layer, such that a first beam and a second beam are respectively generated at the first side and the second side of the active layer; wherein a first reflected beam is generated after the first beam is reflected by the first reflector, the first reflected beam passes through the active layer, the active layer absorbs a portion of the first reflected beam and excites the first beam and the second beam, and a beam that is part of another portion of the first reflected beam and penetrates the active layer is defined as a first transmitted beam;
wherein the second beam and a beam that is part of the first transmitted beam and is reflected by the second reflector are defined as a second reflected beam; wherein the second reflected beam passes through the active layer, and once again excites the active layer to generate the first beam and the second beam;
wherein the second beam and a beam that is part of the first transmitted beam and enters the second optical cavity by penetrating the second reflector are defined as a second transmitted beam; wherein the second transmitted beam resonates between the second reflector and the third reflector to generate a laser beam, and the laser beam is emitted from the light emergent surface of the third reflector.

2. The vertical-cavity surface-emitting laser according to claim 1, wherein the current confinement layer is an oxide layer.

3. The vertical-cavity surface-emitting laser according to claim 1, wherein the first reflector, the second reflector, and the third reflector are each a Bragg reflector.

4. The vertical-cavity surface-emitting laser according to claim 1, wherein a reflectance of the first reflector is greater than or equal to 99.9%.

5. The vertical-cavity surface-emitting laser according to claim 1, wherein a distance between the second reflector and the third reflector is greater than a distance between the first reflector and the second reflector.
